(19) United States
(12) Patent Application Publication
(10) Pub. No.: US 2026/0026360 A1
(43) Pub. Date: Jan. 22, 2026

(54) APPARATUS AND METHOD FOR IMPROVING YIELD OF ADVANCED PACKAGES

(71) Applicant: Chipletz, Inc., Spicewood, TX (US)

(72) Inventors: Siddharth Ravichandran, Austin, TX (US); Michael Su, Austin, TX (US); Michael Alfano, Austin, TX (US); Bryan Black, Austin, TX (US)

(73) Assignee: Chipletz, Inc., Spicewood, TX (US)

(21) Appl. No.: 18/773,795

(22) Filed: Jul. 16, 2024

(51) Int. Cl. H01L 21/48; H01L 23/538

(52) U.S. Cl. CPC H01L 21/4857; H01L 23/5383

(57) ABSTRACT

Each of a selected plurality of different facilities are fabricated into respective tiles, each tile being fabricated using processes best suited to the function of the facility. After tile testing, a selected set of good tiles is fabricated into a single, monolithic substrate in accordance with a selected layout. After substrate testing, the good substrate is then fabricated into a single advanced package.

### FIELD OF INVENTION

The present invention relates to the field of integrated circuits. More particularly, it relates to methods and apparatus to improve yield of advanced packages.

### BACKGROUND

In general, in the descriptions that follow, the first occurrence of each special term of art that should be familiar to those skilled in the art of integrated circuits (“ICs”) and systems will be italicized. In addition, when a term that may be new or that may be used in a context that may be new, that term will be set forth in bold and at least one appropriate definition for that term will be provided.

Hereinafter, reference to a facility shall mean a circuit or an associated set of circuits adapted to perform a particular function regardless of the physical layout of an embodiment thereof. Thus, the electronic elements comprising a given facility may be instantiated in the form of a hard macro adapted to be placed as a physically contiguous facility, or in the form of a soft macro the elements of which may be distributed in any appropriate way that meets speed path requirements. In general, electronic systems comprise many different types of facilities, each adapted to perform specific functions in accordance with the intended capabilities of each system. Depending on the intended system application, the several facilities comprising the hardware platform may be integrated onto a single IC, or distributed across multiple ICs. Depending on cost and other known considerations, the electronic components, including the facility-instantiating IC(s), may be embodied in one or more single-or multi-chip tiles/substrates/packages. However, unless expressly stated to the contrary, the form of instantiation of any facility shall be considered as being purely a matter of design choice.

In the field of advanced packaging, it is known that different functions of the package substrate have contrasting requirements. For example: high-speed input/output (I/O) facilities benefit from thicker dielectric and thick metal; die-to-die I/O facilities benefit from thinner metal for smaller features, no via pads, etc; power delivery networks benefit from thick metal, thin dieletric; and photonics and connectors do not integrate well with traditional substrate process. Further, substrate sizes keep growing, which lowers yield. What is needed, we submit, is a process that will tend to mitigate these problems, and thus tend to improve the yields of advanced packages.

### BRIEF SUMMARY OF THE INVENTION

According to one embodiment, a method is described comprising the steps of: fabricating a first tile comprising a first facility having a first function, using processes best suited to said first function; fabricating a second tile comprising a second facility having a second function substantially different from said first function, using processes best suited to said second function; and fabricating a single, monolithic substrate comprising said first tile and said second tile. An advanced package may then be fabricated comprising said substrate and at least one redistribution layer.

According to one other embodiment, a method is described comprising the steps of: fabricating a first tile comprising a first facility having a first function, using processes best suited to said first function; fabricating a second tile comprising a second facility having a second function substantially different from said first function, using processes best suited to said second function; testing said first tile; testing said second tile; and if said first tile and said second tile each tests good, fabricating said first tile and said second tile into a single, monolithic substrate. An advanced package may then be fabricated comprising said substrate and at least one redistribution layer.

### BRIEF DESCRIPTION OF THE SEVERAL VIEWS OF THE DRAWINGS

FIG. 1 illustrates, in stylized plan view, one possible configuration of an assembly of different, pre-fabricated function tiles into an integrated package substrate;

FIG. 2 illustrates, in stylized cross-section, each of the pre-fabricated function tiles of FIG. 1, before and after integration into a single, coherent package substrate;

FIG. 3, comprising FIGS. 3A, 3B, 3C and 3D, illustrate one possible process flow to manufacture the package substrate of FIG. 2, in accordance with one embodiment of our invention; and

FIG. 4, comprising FIGS. 4A, 4B, 4C and 4D, illustrate an alternate possible process flow to manufacture the package substrate of FIG. 2, in accordance with one other embodiment of our invention;

### DETAILED DESCRIPTION

The following description provides different embodiments for implementing aspects of the present invention. Specific examples of components and arrangements are described below to simplify the explanation. These are merely examples and are not intended to be limiting. For example, the description of a first component coupled to a second component includes embodiments in which the two components are directly connected, as well as embodiments in which an additional component is disposed between the first and second components. In addition, the present disclosure repeats reference numerals in various examples. This repetition is for the purpose of clarity and does not in itself require an identical relationship between the embodiments.

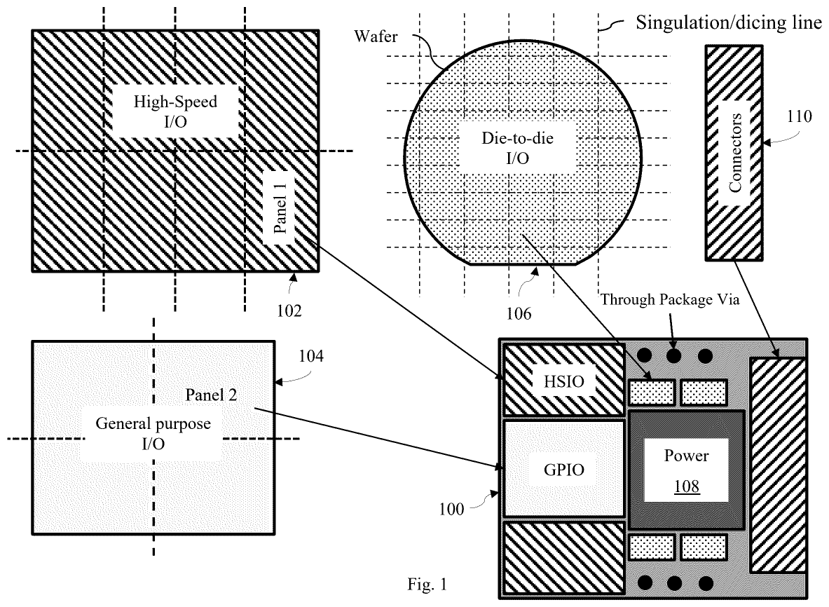

FIG. 1 illustrates, in stylized plan view, a generic process for integrating an assembly of different, pre-fabricated function tiles into an integrated package substrate 100 in accordance with our invention. In this particular substrate 100, we have chosen to integrate: a first tile 102 comprising a high-speed I/O (“HSIO”) facility; a second tile 104 comprising a general purpose I/O (“GPIO”) facility; a third tile 106 comprising a die-to-die I/O (“D2D”) facility; a fourth tile 108 comprising a power facility; and a fifth tile 110 comprising a block of connectors. In accordance with our invention, each of the individual tiles 102-110 is independently manufactured using processes best suited to the function of the respective facility. In this example: the HSIO facility may be fabricated on a tile with thick dielectrics and thick metal; the GPIO facility can be made high-density with few metal layers; the D2D facility may comprise high-density metal for connecting one die to another on the same substrate; the power facility may comprise one or more capacitors, voltage regulator dies and other passive components; and the connectors block may comprise components that are not compatible with traditional substrate fabrication processes, e.g., plug-in external I/O connectors or optical fiber connectors. In addition to the benefits noted above, each facility/tile can be separately tested for functionality before integration into the substrate 100, thus reducing the risk of the substrate 100 being rejected because one (or more) of the facilities/tiles fails substrate test. Further, facilities/tiles that test good can be stockpiled and then used, as needed, in multiple, different package designs.

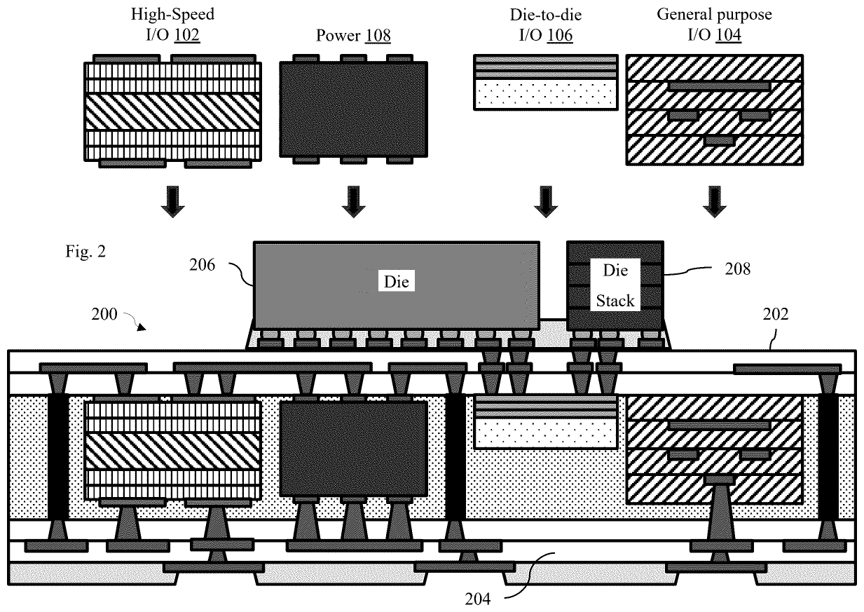

FIG. 2 illustrates, in highly stylized cross-sectional form, the goal of our invention to integrate an assemble of tiles, each implementing a distinctly different function facility requiring distinctly different manufacturing technologies, into a single, monolithic package substrate. In addition to the substrate integrating the respective facilities/tiles 102-110, we have illustrated a fully assembled advance package 200, complete with: upper and lower redistribution layers (“RDLs”) 202 and 204, respectively; a primary die 206, e.g., a CPU; and a die stack 208 typical of a vertically-integrated memory system.

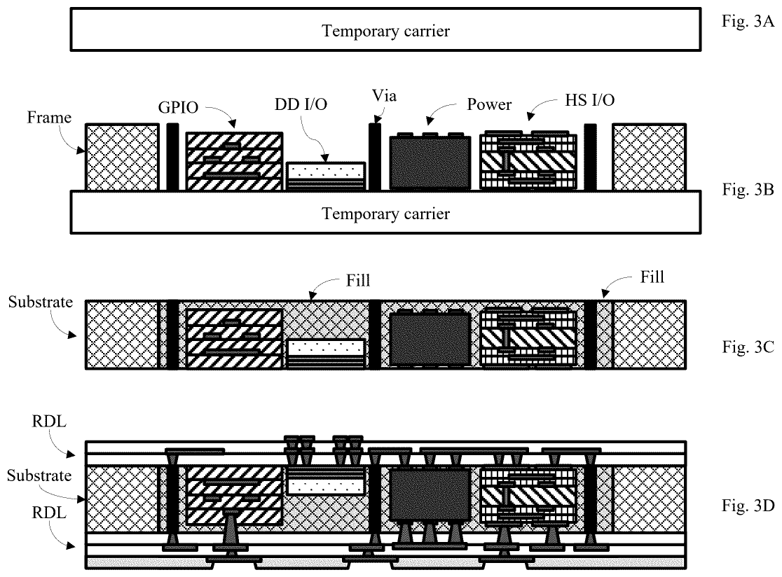

FIG. 3, comprising FIG. 3A through FIG. 3D, illustrates one possible processing sequence in accordance with our invention for fabricating a complete substrate suitable for further processing into the advanced package 200 illustrated in FIG. 2. In FIG. 3A, we fabricate a temporary carrier of convention form with a releasable film layer that will allow us to detach the carrier layer through standard debonding techniques. In FIG. 3B, we attach a frame (sometimes referred to as a core) according to the desired tile layout of the selected set of tiles, and then pick and place all of the selected tiles onto the temporary carrier, each in a position defined by the desired tile layout. In FIG. 3C, we perform a conventional cavity fill and grind to final specifications. Finally, in FIG. 3D, we fabricate the desired upper/lower RDLs. At this point, the substrate is ready for bumping and die attach.

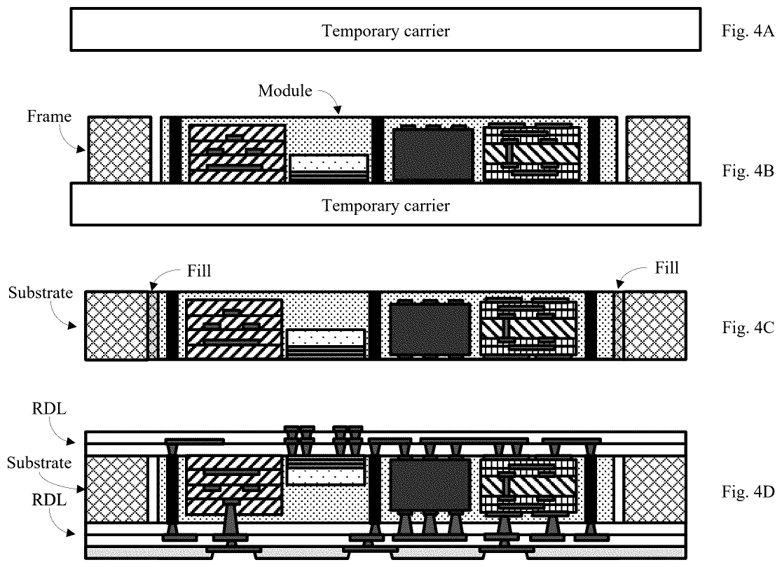

FIG. 4, comprising FIG. 4A through FIG. 5D, illustrates one other possible processing sequence in accordance with our invention for fabricating a complete substrate suitable for further processing into the advanced package 200 illustrated in FIG. 2. In FIG. 4A, we fabricate a temporary carrier of convention form with a releasable film layer that will allow us to detach the carrier layer through standard debonding techniques. In FIG. 4B, we attach a frame (or core) according to the desired tile layout of the selected set of tiles, and then pick and place onto the temporary carrier an integrated module that we have previously fabricated comprising the selected tiles, each in a position defined by the desired tile layout. In FIG. 4C, we perform a conventional cavity fill and grind to final specifications. Finally, in FIG. 4D, we fabricate the desired upper/lower RDLs. At this point, the substrate is ready for bumping and die attach.

The foregoing explanation described features of several embodiments so that those skilled in the art may better understand the scope of the invention. Those skilled in the art will appreciate that they may readily use the present disclosure as a basis for designing or modifying other processes and structures for carrying out the same purposes and/or achieving the same advantages of the embodiments herein. Such equivalent constructions do not depart from the spirit and scope of the present disclosure. Numerous changes, substitutions and alterations may be made without departing from the spirit and scope of the present invention.

Although illustrative embodiments of the invention have been described in detail with reference to the accompanying drawings, it is to be understood that the invention is not limited to those precise embodiments, and that various changes and modifications can be affected therein by one skilled in the art without departing from the scope of the invention as defined by the appended claims. Thus, it will be apparent to one of ordinary skill that this disclosure provides for improved method and apparatus for use in semiconductor packaging.

Apparatus, methods and systems according to embodiments of the disclosure are described. Although specific embodiments are illustrated and described herein, it will be appreciated by those of ordinary skill in the art that any arrangement which is calculated to achieve the same purposes can be substituted for the specific embodiments shown. This application is intended to cover any adaptations or variations of the embodiments and disclosure. For example, although described in terminology and terms common to the field of art, exemplary embodiments, systems, methods and apparatus described herein, one of ordinary skill in the art will appreciate that implementations can be made for other fields of art, systems, apparatus or methods that provide the required functions. The invention should therefore not be limited by the above-described embodiments, methods, and examples, but by all embodiments and methods within the scope and spirit of the invention.

In particular, one of ordinary skill in the art will readily appreciate that the names of the methods and apparatus are not intended to limit embodiments or the disclosure. Furthermore, additional methods, steps, and apparatus can be added to the components, functions can be rearranged among the components, and new components to correspond to future enhancements and physical devices used in embodiments can be introduced without departing from the scope of embodiments and the disclosure. One of skill in the art will readily recognize that embodiments are applicable to future systems, future apparatus, future methods, and different materials.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein.

Terminology used in the present disclosure is intended to include all environments and alternate technologies that provide the same functionality described herein.

1. A method comprising the steps of:
Step 1: using a first tile manufacturing technology to fabricate a first tile comprising a first facility adapted selectively to perform a first function;
Step 2: using a second tile manufacturing technology that is distinctly different from said first tile manufacturing technology to fabricate a second tile comprising a second facility adapted selectively to perform a second function substantially different from said first function; and
Step 3: fabricating a single, monolithic substrate comprising said first tile and said second tile.

2. The method of claim 1 wherein Step 3 is further characterized as comprising the steps of:
Step 4: testing said first tile;
Step 5: testing said second tile; and
Step 6: if said first tile and said second tile each tests good, fabricating said first tile and said second tile into a single, monolithic substrate.

3. The method of claim 2 further comprising the step of:
Step 7: fabricating an advanced package comprising said substrate and at least one redistribution layer.

4. A substrate manufactured in accordance with the process of claim 1.

5. A substrate manufactured in accordance with the process of claim 2.

6. An advanced package manufactured in accordance with the process of claim 3.

7. (canceled).

8. (canceled).

9. (canceled).

10. (canceled).

11. (canceled).

12. (canceled).
